(19) United States
(12) Patent Application Publication
(10) Pub. No.: US 2013/0084405 A1
(43) Pub. Date: Apr. 4, 2013

(54) METHOD FOR FORMING CIRCUITS ON HOUSING BY SPRAYING AND LASER ENGRAVING

(71) Applicants: Young Chae Lee, Qingdao City (CN); Sheng-Hong Wang, Qingdao City (CN); De-Shan Liang, Qingdao City (CN)

(72) Inventors: Young Chae Lee, Qingdao City (CN); Sheng-Hong Wang, Qingdao City (CN); De-Shan Liang, Qingdao City (CN)

(21) Appl. No.: 13/251,301

(22) Filed: Oct. 3, 2011

(51) Int. Cl. H05K 3/46

(52) U.S. Cl. 427/555

(57) ABSTRACT

A method for plating circuits on a housing by spraying and laser engraving is provided. Before manufacturing the circuit, a first spraying layer is formed. The thickness of the first spraying layer is approximately equal to that of the circuit to be formed thereon. Laser engraving is used to form laser engraving areas for forming the circuit metal layer. Then the circuit metal layer is formed by chemical plating, and the thickness of the metal layer is approximately equal to that of the first spraying layer. Then a second spraying layer is applied on both of the metal layer and the first spraying layer so as to present a flat and aesthetic appearance. As the present invention is applied in 2-shot molding, each time the pattern of the circuit is changed, it is only necessary to change the paths in the laser engraving. No more molds modification is needed for changing the pattern of the circuit.

### FIELD OF THE INVENTION

The present invention relates to a process for plating metal layer on a substrate, and in particular to a method for plating circuits on a housing by spraying and laser engraving, which is especially used to form antennas or circuits on housings of mobile devices so as to present a flat and smooth appearance. Furthermore, technologies of spraying and laser engraving are combined in the method of the present invention.

### BACKGROUND OF THE INVENTION

Generally, antenna is formed by RF components on a substrate. The RF components are mainly formed by metal sheets, or soft or hard printed circuits. Recently, technology of molded interconnect device (MID) is developed in the manufacturing of antennas so that the antenna circuit can be formed in a housing of a handset. In manufacturing of MID antenna, a metal layer is formed on a surface of platable plastics (plastics capable of being plated with metal layer) by chemical plating.

Conventionally, there are two ways for manufacturing MID antennas, one is 2-shot molding and the other is laser direct structuring (LDS).

In LDS, a substrate is formed by molding injection of plastics. The materials of the substrate are plastics doped with metals, in that the doped metals can be activated by laser. An area for forming an antenna on the surface of the substrate is activated by laser light. Then the area is plated with metals as an antenna.

2-shot molding performs molding injection twice. It contains the steps of forming a substrate by molding injection of plastics, general, the substrate being a housing of an electronic device. Then in second molding injection operation, one kind of platable plastics is injected into a recess area in the substrate. Finally, a metal layer is formed on the surface of the platable plastic by chemical plating. The metal layer can function as an antenna.

Generally, for protecting the antenna and decoration, the antenna made on the surface of the substrate by 2-shot molding or LDS need to be covered by spraying a layer of paint, but this metal layer of the antenna protrudes from the surface of the housing. Therefore, this will present an unbeautiful housing appearance.

Moreover, by using 2-shot molding to manufacture an antenna on the surface of the substrate, it is needed to adjust the injection mold as the pattern of the antenna is changed. However, this is time and labor consuming.

### SUMMARY OF THE INVENTION

The object of the present invention is to provide a method for plating circuits on a housing by spraying and laser engraving, in that before manufacturing the circuit, a first spraying layer is formed. The thickness of the first spraying layer is approximately equal to that of the circuit to be formed thereon. Then laser engraving is used to remove part of the spraying layer and form a laser engraving area for forming the metal layer of the circuit. Then a circuit metal layer is formed by chemical plating, and the thickness of the metal layer is approximately equal to that of the first spraying layer. Then a second spraying layer is formed on both of the metal layer and the first spraying layer so as to present a flat and smooth surface and thus have an aesthetic appearance. As the present invention is applied in 2-shot molding, each time the pattern of the circuit is changed, it is only necessary to change the paths in the laser engraving. No more molds modification is needed for changing the pattern. Therefore, the time period for adjusting the circuit is shortened effectively.

The various objects and advantages of the present invention will be more readily understood from the following detailed description when it is read in conjunction with the appended drawings.

### BRIEF DESCRIPTION OF THE DRAWINGS

FIG. 1A is a perspective view showing the first spraying step in the first embodiment of the present invention.

FIG. 1B is a cross sectional view of FIG. 1A.

FIG. 2 shows the laser engraving step in the first embodiment of the present invention.

FIG. 3 shows the chemical plating step in the first embodiment of the present invention.

FIG. 4 shows the second spraying step in the first embodiment of the present invention.

FIG. 5A shows the application of the first embodiment of the present invention, where structure of the substrate is illustrated.

FIG. 5B is a cross sectional view of FIG. 5A.

FIG. 6 shows the spraying step in the application of the first embodiment.

FIG. 7 shows the laser engraving step in the application of the first embodiment.

FIG. 8 shows the laser activation step in the application of the first embodiment.

FIG. 9 shows the step for forming the antenna, joint and path therebetween in the application of the first embodiment.

FIG. 10 shows the second spraying step in the application of the first embodiment.

FIG. 11A is a perspective view showing the spraying step in the second embodiment of the present invention, where the right side is a cross sectional view.

FIG. 11B is a cross sectional view of FIG. 11A.

FIG. 12 shows the laser engraving step in the second embodiment of the present invention.

FIG. 13 shows the chemical plating step in the second embodiment of the present invention.

FIG. 14 shows the second spraying step in the second embodiment of the present invention.

FIG. 15A shows the structure of the substrate in the application of the second embodiment of the present invention.

FIG. 165B is a cross sectional view of FIG. 15A.

FIG. 17 shows the laser engraving step in the application of the second embodiment.

FIG. 18 shows the second step for forming the antenna, the joint and the path therebetween in the application of the second embodiment of the present invention.

FIG. 19 shows the second spraying step in the application of the second embodiment.

FIG. 20A shows the structure of the substrate in the third embodiment of the present invention.

FIG. 20B is a cross sectional view of FIG. 20A.

FIG. 21 shows the second molding and the first spraying steps in the third embodiment of the present invention.

FIG. 22 shows the laser engraving step in the third embodiment of the present invention.

FIG. 23 shows the chemical plating step in the third embodiment of the present invention.

FIG. 24 shows the second spraying step in the third embodiment of the present invention.

FIG. 25 shows the structure of the substrate in the application of the third embodiment of the present invention.

FIG. 26 shows the second molding and the first spraying steps in the application of the third embodiment of the present invention.

FIG. 27 shows the laser engraving step in the application of the third embodiment of the present invention.

FIG. 28 shows the step for forming the antenna, the joint and the path therebetween in the application of the third embodiment of the present invention.

FIG. 29 shows the second spraying step after the step of FIG. 28.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

The present invention relates to a method for plating circuits on a housing by spraying and laser engraving. In the method, a first spraying layer is formed. The thickness of the first spraying layer is approximately equal to that of circuits to be formed. Then a laser engraving is used to remove part of the spraying layer and form a laser engraving area for forming the metal layer. Then a circuit metal layer is formed by chemical plating, and the thickness of the metal layer is approximately equal to that of the first spraying layer. Then a second spraying layer is formed on both of the metal layer and the first spraying layer so that the second spraying layer presents a flat and smooth surface and thus has an aesthetic appearance. The present invention is suitable for three different types of manufacturing processes, which will be described herein. However in the following, the manufacturing of an antenna on a housing is used as an example, but this is not used to confine the scope of the present invention.

In fact, the present invention can be applied to form various metal circuits.

The first embodiment of the present invention is described herein. A substrate 10 (a substrate of MID) is used for forming an antenna. The substrate 10 is made of one kind of plastics which are able to be chemically plated after laser activation, for example, plastics of LDS (laser direct structuring) grade.

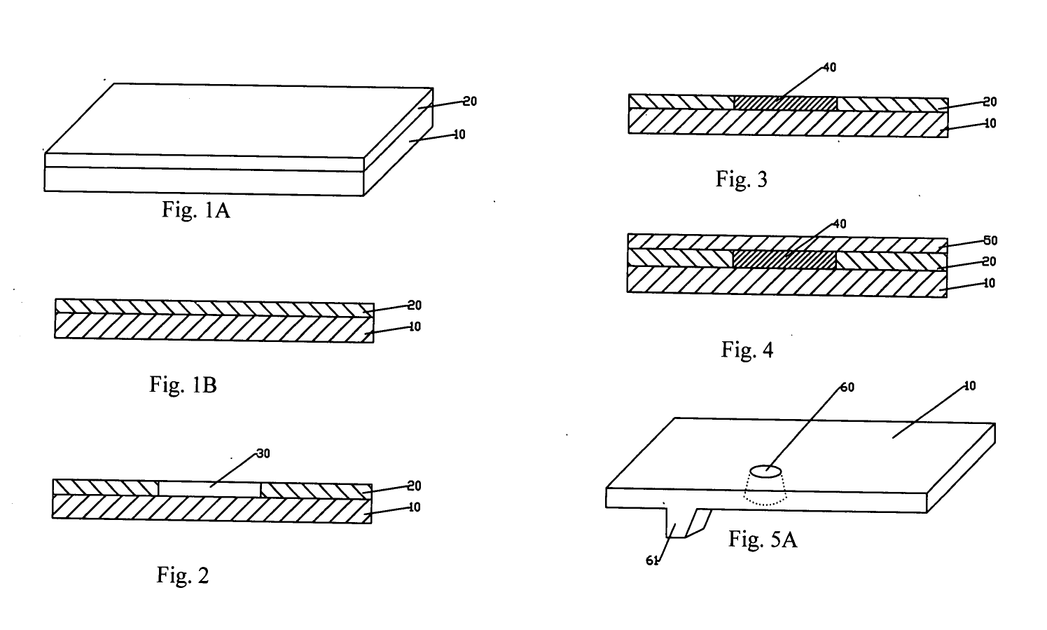

A layer of spraying layer 20 is sprayed on the substrate 10, for example, by spraying a layer of paint. The thickness of the first spraying layer 20 is approximately equal to that of the antenna metal layer (referring to FIGS. 1A and 1B).

A part of the first spraying layer 20 corresponding to the patterns of an antenna to be formed thereon is removed by laser engraving so as to expose a laser engraving area 30, as illustrated in FIG. 2.

The surface of the laser engraving area 30 on the substrate 10 is then activated by laser.

Further, a metal layer 40 is formed on the laser engraving area 30 by chemical plating (referring to FIG. 3). The thickness of the metal layer 40 formed by chemical plating is approximately equal to that of the first spraying layer 20, that is, the thickness of the metal layer 40 is approximately equal to that of the spraying layer 20 on a periphery thereof.

A second spraying layer 50 is further sprayed on both of the metal layer 40 and the first spraying layer 20 (referring co FIG. 4). Therefore, the second spraying layer 50 will effectively cover the metal layer 40 on the substrate 10 to have a smooth and flat appearance.

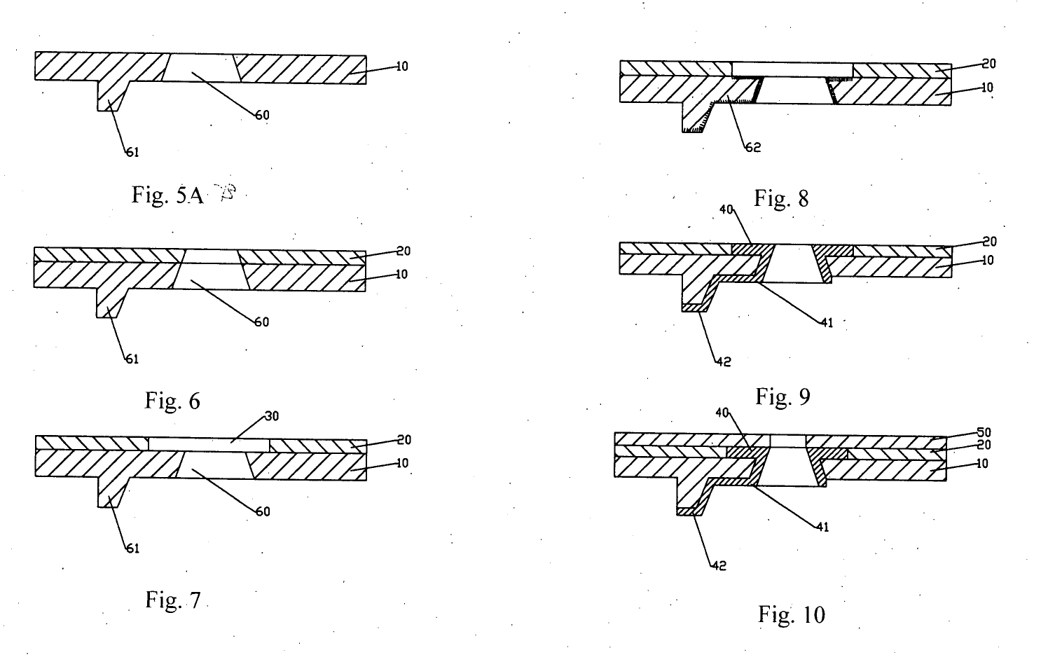

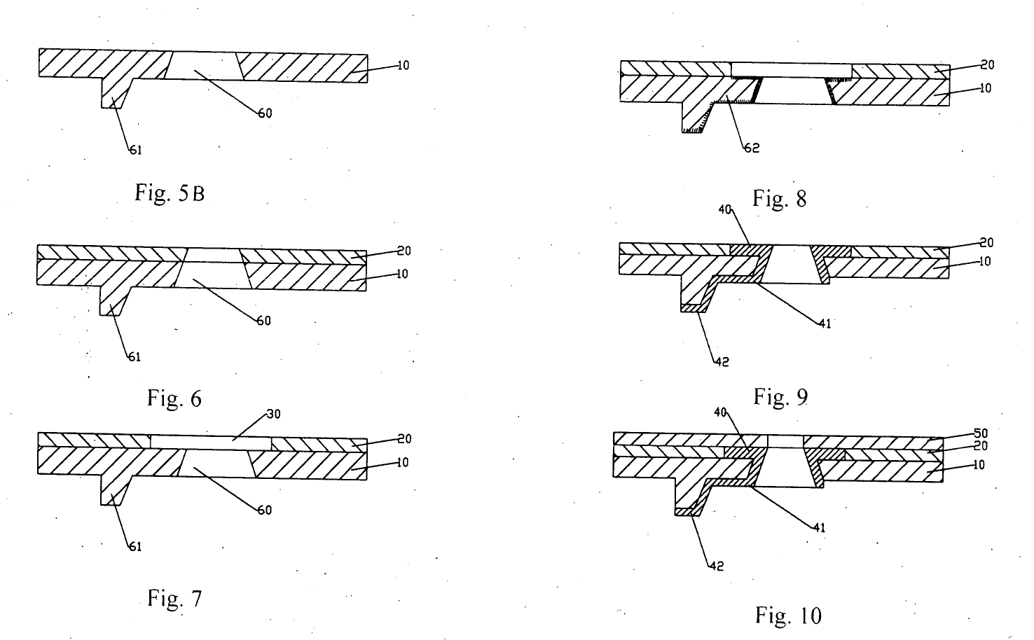

With reference to FIGS. 5A and 5B, a first application of the present invention is illustrated. In that, a joint is needed to be formed on a backside of the substrate 10 for electrically grounding or signal transmission. In the method of the present invention, a through hole 60 is formed in the substrate 10, preferably, the through hole 60 has a taper shape or a shape like a hopper with a small upper side and a large lower side. This shape is beneficial for aesthetic appearance and laser activation. In the present invention, the joint is formed on a protrusion 61 at the backside of the substrate 10 (referring to FIGS. 5A and 5B).

The upper side of the substrate 10 is sprayed with a first spraying layer 20 (referring to FIG. 6). The substrate 10 is made of one kind of LDS grade plastics. A part of the spraying layer 20 corresponding to the circuit pattern of the antenna is removed so as to expose the underneath substrate 10. A laser engraving area 30 is formed as illustrated in FIG. 7. Then the area containing the antenna circuit, the joint and a path connecting the antenna and the joint are activated by laser so as to form a laser activated areas 62 (see FIG. 8). Then, a metal layer 40 is formed on the laser activated area 62 by chemical plating (referring to FIG. 9) which includes the antenna circuit 40, the joint 42 and the path 41.

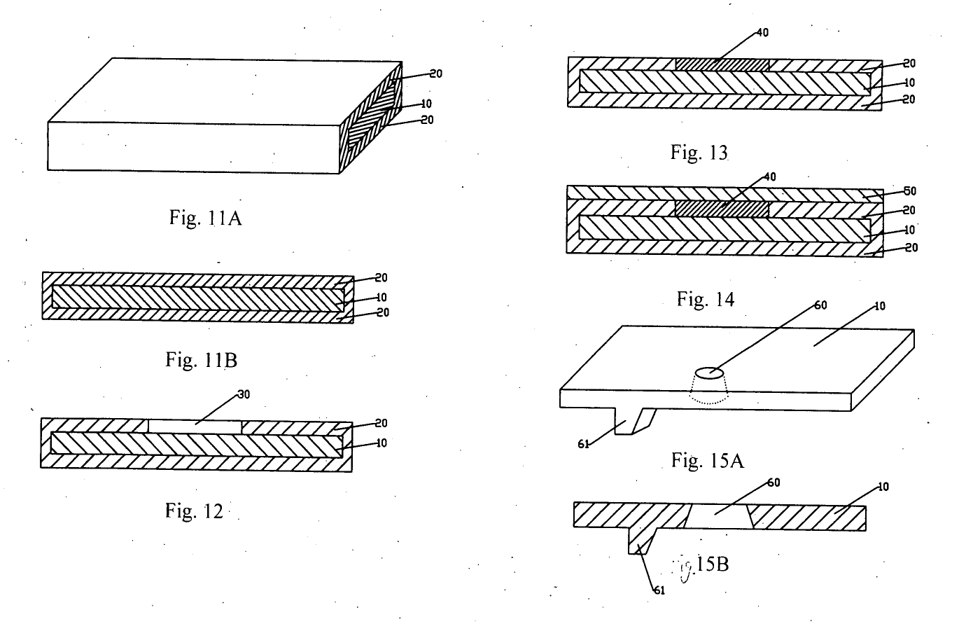

Finally, a second spraying layer 50 is further sprayed on both of the metal layer 40 and the first spraying layer 20 (referring to FIG. 10). Therefore, the second spraying layer 50 will effectively cover the antenna metal layer 40 underneath so as to have a flat and smooth appearance.

The second embodiment of the present invention will be described herein. However those elements having the same functions as those on the first embodiment are identified by the same numerals. In the second embodiment, the substrate 10 is made of one kind of platable plastics (plastics capable of being plated with metal directly without laser activation), for example, the substrate 10 is made of Acrylonitrile-Butadiene-Styrene copolymers (ABS) or the mixture of ABS and polycarbonate (PC). The step of this embodiment will be described herein.

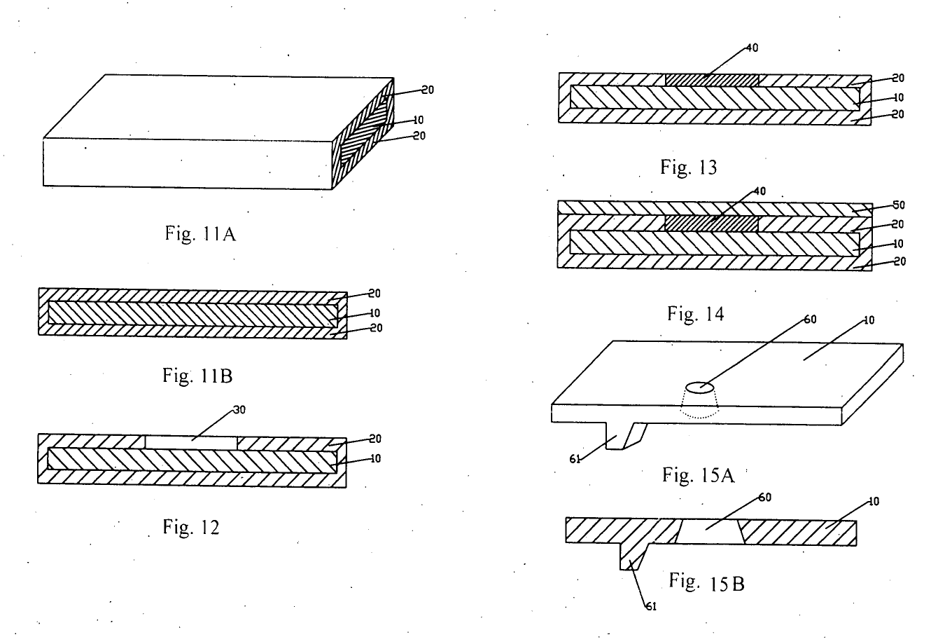

Firstly, the platable plastics are used in making substrate 10 for forming an antenna circuit. The surface of the substrate 10 is sprayed with a first spraying layer 20 (for example, covering with a layer of paint). The thickness of the spraying layer 20 is approximately equal to that of an antenna circuit to be formed thereon (referring to FIGS. 11A and 11B, in that a lateral side of FIG. 11A is a cross sectional view).

A part of the first spraying layer 20 corresponding to the pattern of the antenna circuit to be formed is removed by laser engraving so as to expose a laser engraving area 30, as illustrated in FIG. 12. Further, a metal layer 40 is formed on the laser engraving area 30 by chemical plating (referring to FIG. 13). The thickness of the metal layer 40 formed by chemical plating is approximately equal to that of the first spraying layer 20, that is, the thickness of the metal layer 40 is approximately equal to that of the first spraying layer 20 on a periphery thereof.

A second spraying layer 50 is further sprayed on both of the metal layer 40 and the first spraying layer 20 (referring to FIG. 14). Therefore, the second spraying layer 50 will effectively cover the metal layer 40 on the substrate 10 so as to have smooth and flat appearance.

Since the chemical roughening operation in the chemical plating will coarsen the surface of the spraying layer 20, the chemical roughening operation can be performed before spraying of the first spraying layer 20.

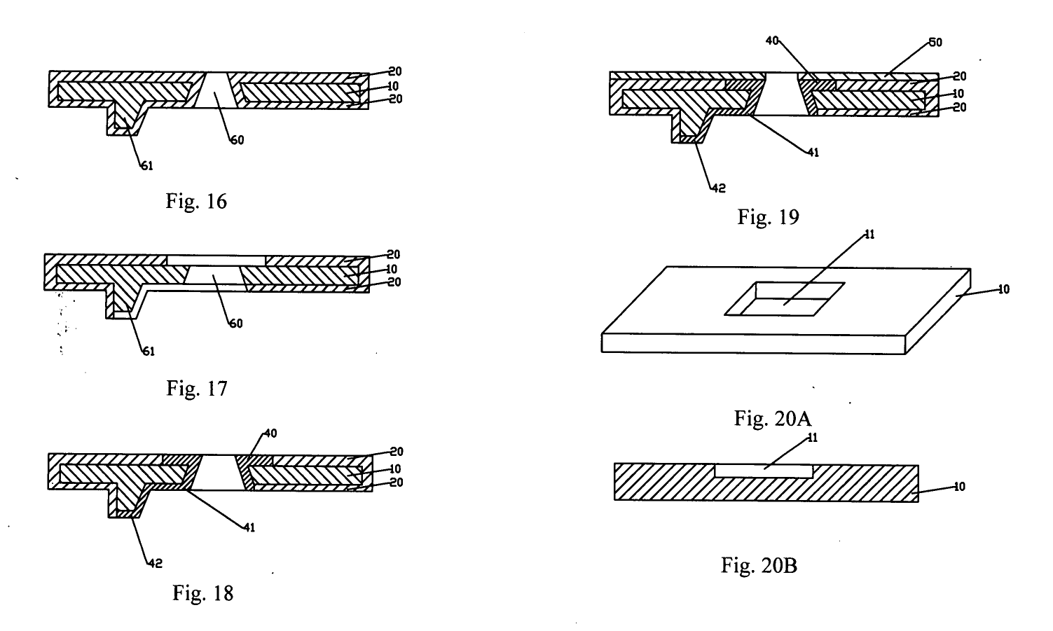

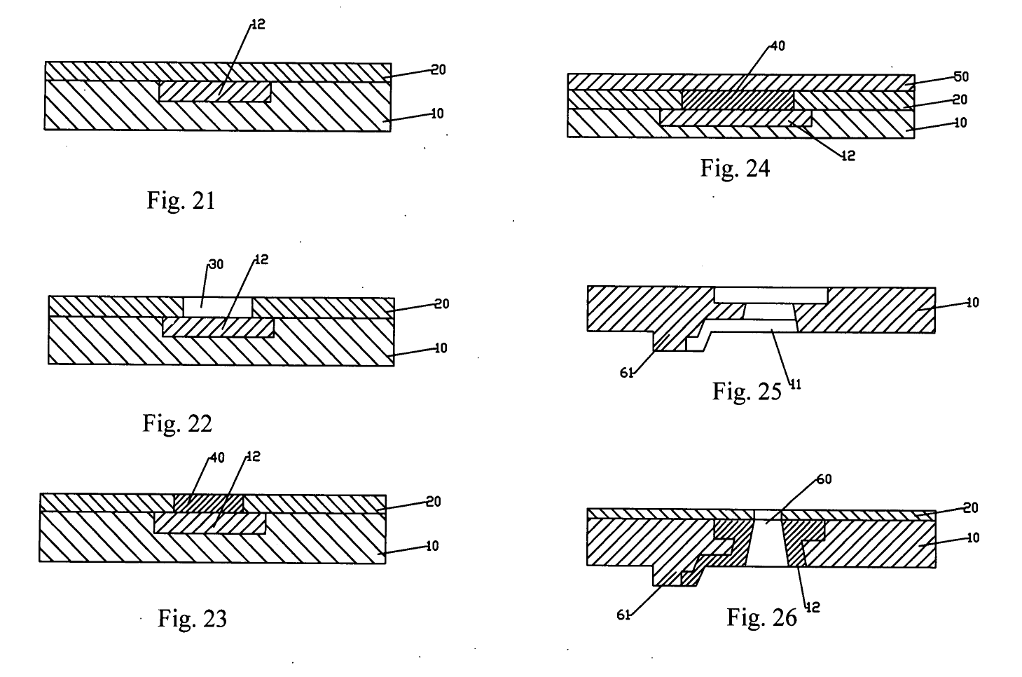

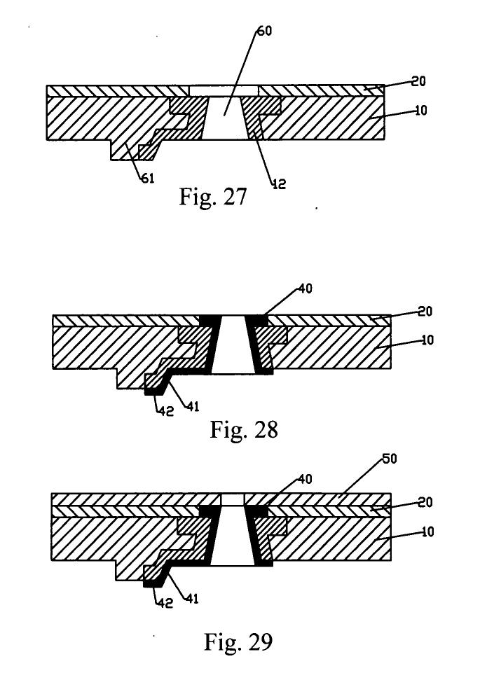

With reference to FIGS. 15A and 15B, the application of the second embodiment of the present invention is illustrated. In that a joint is needed to be formed on the backside of the substrate 10 for electrically grounding or signal transmission. In the method of the present invention, a through hole 60 is formed in the substrate 10 and through the platable plastic, preferably, the through hole 60 has a taper shape or a shape like a hopper with a small upper side and a large lower side. This shape is beneficial for laser engraving and obtaining an aesthetic upper side appearance. In the present invention, the joint is formed on a protrusion 61 at the backside of the substrate 10.

A periphery of the substrate 10 is sprayed with a first spraying layer 20 (referring to FIG. 16). A part of the spraying layer 20 corresponding to the circuit pattern of the antenna, the joint and a pith connecting the antenna and the joint is removed by laser engraving so as to expose the underneath substrate 10 as illustrated in FIG. 17. Then, the expose area of the substrate 10 is plated by chemical plating (referring to FIG. 18) so as to form the antenna circuit 40, the joint 42 and the path 41.

Finally, a second spraying layer 50 is further sprayed on the upper side of the substrate 10 to cover the metal layer 40 and a part of the first spraying layer 20 on the upper side of the substrate (referring to FIG. 10). Therefore, the second spraying layer 50 will effectively cover the antenna metal layer 40 underneath to have a flat and smooth appearance.

The third embodiment of the present invention will be described herein. However those elements having the same functions as those on the third embodiment are identified by the same numerals. In this embodiment, the method of the present invention is applied to the 2-shot molding.

In the first molding process, a non-platable plastic (such as polycarbonate) is used to make the substrate 10 for forming an antenna circuit thereon. A recess 11 for forming the antenna circuit is formed on the substrate 10, referring to FIGS. 20A and 20B. Then second molding process is preformed on the substrate 10. One kind of platable plastics is filled into the recess 11 for forming a platable area 12. A first spraying layer 20 is sprayed on the substrate 10 (including the platable area 12). The thickness of the first spraying layer 20 is approximately equal to that of an antenna circuit to be formed on the substrate 10 (see FIG. 21).

A part of the first spraying layer 20 in the platable area 12 corresponding to the pattern of the antenna circuit to be formed is removed by laser engraving so as to expose a laser engraving area 30, as illustrated in FIG. 22. Further, a metal layer 40 is formed on the laser engraving area 30 by chemical plating (referring to FIG. 23). The thickness of the metal layer 40 formed by chemical plating is approximately equal to that of the first spraying layer 20, that is, the thickness of the metal layer 40 is approximately equal to that of the spraying layer 20 on a periphery thereof.

A second spraying layer 50 is further sprayed on both of the metal layer 40 and the first spraying layer 20 (referring to FIG. 24). Therefore, the second spraying layer 50 will effectively cover the metal layer 40 on the substrate 10 so as to have smooth and flat appearance.

Similarly, to avoid coarsening the surface of the spraying layer 20 caused by the chemical roughening operation in the chemical plating, the chemical roughening operation can be performed before the spraying of the first spraying layer 20.

The application of the third embodiment of the present invention is illustrated. In that, a joint is needed to be formed on the backside of the substrate 10 for electrically grounding or signal transmission.

In the first molding process, a non-platable plastic (such as polycarbonate) is used to make the substrate 10 for forming an antenna circuit thereon. In the present invention, the joint is formed on a protrusion 61 at the backside of the substrate 10 (referring to FIG. 25). Recess 11 is formed, which contains areas of the antenna circuit to be formed, the joint and the path connecting the antenna circuit and the joint, as shown in FIG. 25.

Then the second molding process is preformed on the substrate 10. A platable plastic is filled into the recess 11 for forming a platable plastics area 12. A through hole 60 is formed in the platable area 12 and through the platable plastic in the recess, preferably, the through hole 60 has a taper shape or a shape like a hopper. The lager side of the through hole 60 is at the backside of the substrate 10. Then, a spraying layer 20 is sprayed on an upper surface of the substrate 10 (including the platable area 12), see FIG. 26. A part of the first spraying layer 20 corresponding to the antenna pattern is removed by laser engraving so as to expose the platable plastic underneath as illustrated in FIG. 27. Then the circuit metal layers corresponding to the antenna circuit, the joint and the path connecting the antenna circuit and the joint is formed by chemical plating as illustrated in FIG. 28. The metal layer contains the antenna circuit 40, the joint 42 and the path 41.

Finally, a second spraying layer 50 is further sprayed on both of the antenna circuit 40 and the first spraying layer 20 and will cover the circuit metal layer 40 and the first spraying layer 20 with a flat and smooth appearance (referring to FIG. 29).

It should be noted that in the present invention, the process for forming an antenna on a substrate is described. However the present invention can be used to other circuits.

In the present invention, before manufacturing the antenna, a first spraying layer is formed. The thickness of the first spraying layer is approximately equal to that of the circuit to be formed. Then a laser engraving is used to remove the spraying layer and form a laser engraving area for forming the metal layer. Afterward, the circuit metal layer is formed by chemical plating, and the thickness of the metal layer is approximately equal to that of the first spraying layer on the periphery thereof. Then a second spraying layer is formed on both of the metal layer and the first spraying layer so as to form a flat and smooth appearance, and thus the second spraying layer presents an aesthetic appearance. Furthermore, as the present invention is used to 2-shot molding, laser engraving is used to form a laser engraving area for forming the metal layer. Therefore, each time the pattern of the circuit is changed, it is only necessary to change the paths in the laser engraving process. No more mold modification is needed for adjusting the circuit pattern. Therefore, the time period for adjusting the circuit is shortened effectively.

The present invention is thus described, but it will be obvious that the same may be varied in many ways. Such variations are not to be regarded as a departure from the spirit and scope of the present invention, and all such modifications as would be obvious to one skilled in the art are intended to be included within the scope of the following claims.

1. A method for forming circuits on a housing by spraying and laser engraving, comprising the steps of:
spraying a first spraying layer on a substrate; the thickness of the first spraying layer being approximately equal to that of a circuit metal layer to be formed on the substrate; the substrate being made of one kind of material which can be plated by chemical plating after laser activation;
removing a part of the first spraying layer corresponding to the pattern of the circuit to be formed on the substrate to expose an underneath substrate which is defined as a laser engraving area;
performing laser activation on the laser engraving area;
forming a circuit metal layer on the laser engraving area by chemical plating; the thickness of the circuit metal layer being approximately equal to that of the first spraying layer; and
spraying a second spraying layer on both of the circuit metal layer and the first spraying layer so that the second spraying layer will cover both of the circuit metal layer and the first spraying layer with a flat and smooth appearance.

2. The method as claimed in claim 1, further comprising the steps of:
forming a through hole in the substrate, wherein a backside of the substrate will be formed with a joint for electrically grounding or signal transmission;
performing laser activation on an area at the backside of the substrate corresponding to the joint and a path connecting the circuit pattern and the joint so as to form laser activation areas; and
plating the laser activation areas by chemical plating to form a metal layer which contains the circuit, the joint and the path.

3. The method as claimed in claim 1, wherein the circuit is an antenna circuit.

4. A method for forming circuits on a housing by spraying and laser engraving comprising the steps of:
spraying a first spraying layer on a substrate; the substrate being made of one kind of platable plastics which can be directly plated by chemical plating;
removing a part of the first spraying layer corresponding to the pattern of a circuit to be formed on the substrate by laser engraving so as to expose an underneath substrate which is defined as a laser engraving area; and
forming a circuit metal layer on the laser engraving area by chemical plating.

5. The method as claimed in claim 4, wherein the thickness of the circuit metal layer is approximately equal to that of the first spraying layer; and after chemical plating, further comprising the step of:
spraying a second spraying layer on both of the circuit metal layer and the first spraying layer so that the second spraying layer will cover both of the circuit metal layer and the first spraying layer with a flat and smooth appearance.

6. The method as claimed in claim 4, further comprising the steps of:
forming a through hole in the substrate and a joint on the backside of the substrate for electrically grounding or signal transmission;
spraying the substrate on all the surface of the substrate;
performing laser engraving on an area at the backside of the substrate corresponding to the joint; and a path connecting the circuit pattern and the joint; and
chemically plating the area corresponding to the joint; and the path connecting the circuit pattern and the joint so as to form a metal layer which contains the circuit, the joint and the path.

7. The method as claimed in claim 4, wherein the platable plastic is selected from one of Acrylonitrile-Butadiene -Styrene copolymers (ABS) and mixture of ABS and polycarbonate (PC).

8. The method as claimed in claim 4, wherein the circuit is an antenna circuit.

9. The method as claimed in claim 4, wherein a chemical roughening step for chemical plating is performed before spraying of the first spraying layer.

10. A method for forming circuits on a housing by spraying and laser engraving, comprising the steps of:
forming a recess on a substrate; the recess containing an area to form a circuit; the substrate being made of one kind of non-platable plastics;
injecting one kind of platable plastics into the recess of the substrate to form a platable area which can be directly plated by chemical plating;
spraying a first spraying layer on the substrate including the platable area;
removing a part of the first spraying layer corresponding to the pattern of the circuit to be formed on the substrate by laser engraving so as to expose underneath platable plastic which is defined as a laser engraving area; and
forming a circuit metal layer on the laser engraving area by chemical plating.

11. The method as claimed in claim 10, wherein the thickness of the circuit metal layer being approximately equal to that of the first spraying layer; and after forming the circuit metal layer, further comprising the step of:
spraying a second spraying layer on both of the circuit metal layer and the first spraying layer so that the second spraying layer will cover both of the circuit metal layer and the first spraying layer with a flat and smooth appearance.

12. The method as claimed in claim 10, further comprising the steps of:
forming a through hole in the substrate and through the platable plastic in the recess, where a backside of the substrate will be formed with a joint for electrically grounding or signal transmission;
forming recesses on area for forming the joint and a path connecting the antenna circuit and the joint;
injecting one kind of platable plastics into the recesses for forming the joint and the path, which defines platable areas;
spraying a layer on the platable areas;
laser engraving the spraying layer in areas corresponding to the pattern of the circuit; and
chemically plating the the circuit, the joint and the path so as to form a metal layer which is the circuit, the joint and the path.

13. The method as claimed in claim 10, wherein the non-platable plastic is polycarbonate (PC) and the platable plastic is Acrylonitrile-Butadiene -Styrene copolymers (ABS) or mixture of ABS and PC.

14. The method as claimed in claim 10, wherein the circuit is an antenna circuit.

15. The method as claimed in claim 10, wherein a chemical roughening step for chemical plating is performed before spraying the first spraying layer.
